(19) United States
(12) Patent Application Publication
(10) Pub. No.: US 2020/0409437 A1
(43) Pub. Date: Dec. 31, 2020

(54) HEAT DISSIPATING ELEMENTS

(71) Applicant: HEWLETT-PACKARD DEVELOPMENT COMPANY, L.P., SPRING, TX (US)

(72) Inventors: KUAN-TING WU, TAIPEI CITY (TW); CHENG-FENG LIAO, TAIPEI CITY (TW); WEI-CHUNG CHEN, TAIPEI CITY (TW)

(21) Appl. No.: 16/964,365

(22) PCT Filed: Mar. 19, 2018
(86) PCT No.: PCT/US2018/023196

§ 371 Date: Jul. 23, 2020

(51) Int. Cl. G06F 1/20; H05K 7/20; G06F 1/16

(52) U.S. Cl. CPC G06F 1/203; G06F 1/1656; H05K 7/2039

(57) ABSTRACT

Examples disclosed herein relate to heat dissipating elements of a computing device. The computing device including a chassis to house a heat generating element and a moveable member within the chassis in a closed state. The moveable member is to transition from the closed state to an open state. The computing device further includes a heat dissipating element coupled to the moveable member to be exposed to an external environment in the open state. The heat dissipating element to be thermally coupled to the heat generating element in a closed state of the moveable member. The computing device also includes a motor to move the moveable member from the closed state to the open state in response to a temperature within the chassis exceeding a threshold.

### BACKGROUND

Electrical and mechanical devices may generate heat during operation. The heat generated during operation of a device may damage the device or make the device too hot to safely handle. Various methods of reducing the impact of generated heat have been devised.

### BRIEF DESCRIPTION OF THE DRAWINGS

The following detailed description references the drawings, wherein:

FIG. 1 is a block diagram of an example computing device.

FIG. 2A is a block diagram of an example computing device.

FIG. 2B is a block diagram of an example computing device including possible additional example components of the computing device of FIG. 2.

FIGS. 3A-3B are examples of a computing device including a heat dissipating element.

FIG. 3C is an example computing device including possible additional example components of the computing device of FIG. 3A.

FIG. 4A is an example of a computing device including a heat dissipating element,

FIG. 4B is an example of a computing device including possible additional example components of the computing device of FIG. 4A.

FIG. 5 is an example of a heat dissipating element.

FIGS. 6A-6B are examples of a computing device including heat dissipating elements.

FIGS. 7A-7B are examples of a computing device including heat dissipating elements.

FIG. 8 is an example of a computing device including heat dissipating elements.

FIG. 9A is an example of a computing device including heat dissipating elements.

FIG. 9B is an example of a computing device including possible additional example components of the computing device of FIG. 9A.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

A “heat dissipating element” may be used to dissipate heat generated in an electrical or mechanical device. Such devices may include multiple heat dissipating elements to dissipate generated heat. In such devices, a heat dissipating system may include multiple different components to operate together to dissipate heat. Some heat dissipating elements operate by absorbing heat from heat generating devices or components and dissipating the absorbed heat to a surrounding environment. For example, heat dissipating elements may include a large surface area from which heat may be dissipated. In some such heat dissipating elements, a protrusion(s) or fin(s) may be used to provide a larger surface area from which heat may be dissipated to the surrounding environment. Some heat dissipating systems may include fans and other air moving devices to introduce air to help dissipate heat and/or cool down heat generating elements. As electronic devices become smaller, there may be less room for different types heat dissipating elements within a device. For example, as computing devices become smaller and there is a desire for quieter devices, the use of a fan to dissipate heat may be disfavored. However, the use of fewer types of heat dissipating elements may increase the risk of a device overheating. To manage generated heat, such devices may need additional heat dissipation mechanisms to ensure that a device's internal temperature does not exceed operational thresholds.

To address these issues, in the examples described herein, a computing device is described which may selectively open a moveable member to move a heat dissipating element into an environment external to the chassis of the computing device. In examples, the computing device may move the heat dissipating element to protrude from a chassis when a threshold temperature is exceeded. In such examples, the heat dissipating element may be exposed to a larger external environment and may dissipate heat thereto rather than to an environment internal to the chassis of the computing device. In some examples, opening the moveable member may further expose components internal to the chassis to an air flow from the external environment. In this manner, examples described herein may manage heat dissipation within a chassis of a computing device.

Examples disclosed herein relate to a computing device. In examples, the computing device may include a chassis to house a heat generating element and a moveable member within the chassis in a closed state. In examples, the moveable member may transition from the closed state to an open state. In such examples, the computing device further may include a heat dissipating element coupled to the moveable member to be exposed to an external environment in the open state. In examples, the heat dissipating element may be thermally coupled to the heat generating element in a closed state of the moveable member. In examples, the computing device may also include a motor to move the moveable member from the closed state to the open state in response to a temperature within the chassis exceeding a threshold. In examples, the heat dissipating element includes a heat insulation layer to insulate a portion of the heat dissipating element. In some examples, the heat insulation layer may insulate a top surface of the heat dissipating element. In other examples, the heat insulation layer may insulate a bottom surface of the heat dissipating element. In some example computing devices, the heat dissipating element, in the open state, may be thermally coupled to the heat generating element. Some computing devices may further include a keyboard tray integrated into a surface of the chassis. In such an example, the surface the keyboard tray is integrated into may be parallel to the moveable member along a direction of ejection of the moveable member.

Examples disclosed herein relate to a computing device including a chassis to house a heat generating element and a first moveable member within the chassis in a closed state. In examples, the first moveable member may eject from a first surface of the chassis to transition from the closed state to an open state. In examples, the chassis may be open to an external environment in the open state of the first moveable member. In examples, the computing device may also include a first heat dissipating element coupled to the first moveable member to be exposed to the external environment in the open state of the first moveable member. In examples, the first heat dissipating element may be thermally coupled to the heat generating element in a closed state of the first moveable member. In examples, the computing device further includes a second moveable member within the chassis in a closed state of the second moveable member. In such examples, the second moveable member may eject from a second surface of the chassis in an open state of the second moveable member. In examples, the first surface of the computing device may be disposed opposite the second surface of the computing device. In examples, the chassis may open to the external environment in the open state of the second moveable member. In examples, the computing device additionally includes a motor to eject the first moveable member from the chassis in response to a temperature within the chassis exceeding a first threshold. In some such examples, the motor is to move the second moveable member into the open state of the second moveable member in response to a temperature within the chassis exceeding a second threshold. In some examples, the first heat dissipating element includes a plurality of fins extending upwards from the first moveable member. In other examples, the first heat dissipating element includes a plurality of fins extending downwards from the first moveable member. In some examples, the first heat dissipating element includes a heat insulation layer to insulate a portion of the first heat dissipating element.

Another example computing device includes a chassis to house a heat generating element, a first moveable member, a first heat dissipating element, a second moveable member, a second heat dissipating element, and a motor. In such example computing devices, the first moveable member may be within the chassis in a closed state. In examples, the first moveable member is to eject from the chassis to transition from the closed state to an open state. In examples, the chassis may be open to an external environment in the open state of the first moveable member. In such example computing devices, the first heat dissipating element is coupled to the first moveable member to be exposed to the external environment in the open state of the first moveable member. In examples, the first heat dissipating element is to be thermally coupled to the heat generating element. Further in such example computing devices, the second moveable member may be within the chassis in a closed state of the second moveable member. In examples, the second moveable member may eject from the chassis to transition from the closed state of the second moveable member to an open state of the second moveable member. In such examples. the chassis may be open to the external environment in the open state of the second moveable member. In examples, the second heat dissipating element may be coupled to the second moveable member to be exposed to the external environment in the open state of the second moveable member. In examples, the second heat dissipating element may be thermally coupled to the heat generating element. In example computing devices, the motor may eject the first moveable member and the second moveable member from the chassis in response to a temperature within the chassis exceeding a first threshold temperature.

In some example computing devices, the first heat dissipating element and the second heat dissipating element include a plurality of fins and a heat insulation layer. In some example, the motor is to eject the second moveable member into the open states of the second moveable member in response to a temperature within the chassis exceeding a second threshold temperature. In some examples, the second threshold temperature may differ from the first threshold temperature of the computing device. In example computing devices, the first heat dissipating element and the second heat dissipating element may be thermally isolated from the heat generating component in the open state.

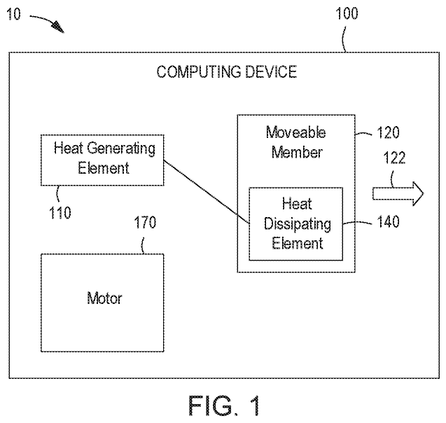

Referring now to the drawings, FIG. 1 is a block diagram of an example computing device 10. In examples, computing device 10 may include a chassis 100, a heat generating element 110, a moveable member 120, a heat dissipating element 140, and a motor 170. A “computing device” may be an electrical device including heat generating elements, such as a desktop computer, laptop (or notebook) computer, workstation, tablet computer, mobile phone, smartphone, smart watch, smart wearable glasses, smart device, server, blade enclosure, imaging device, or any other processing device. As used herein, the term “chassis” refers to an outer structural framework of a device. In examples, a chassis may house components of the device therein. In examples, computing device 10 may be any type of computing device.

In examples, chassis 100 may house a heat generating element 110 and a motor 170. In examples, moveable member 120 may be coupled to first heat dissipating element 140. In examples, the term “couple,” “coupled,” and/or “couples” is intended to include suitable indirect and/or direct connections. Thus, if a first component is described as being coupled to a second component, that coupling may, for example, be: (1) through a direct electrical and/or mechanical connection, (2) through an indirect electrical and/or mechanical connection via other devices and connections, (3) through an optical electrical connection, (4) through a wireless electrical connection, (5) a communicative connection, and/or (6) another suitable coupling. In examples, chassis 100 may house moveable member 120 and heat dissipating element 140 in a closed state. In contrast, in an open state, moveable member 120 and heat dissipating element 140 may be disposed outside a chassis 100.

In examples, heat generating element 110 may be any electrical or mechanical component which may generate heat in a computing device. In some examples, heat generating element 110 may include a central processing unit (CPU), a printed circuit board (PCB), a processor, a memory, a battery, etc. In examples, heat generating element 110 may be disposed in any location within chassis 100 of computing device 10. In examples, heat generating element 110 may be thermally coupled to heat dissipating element 140. As used herein, if a first component is described as being “thermally coupled” to a second component, that coupling may be any coupling to provide heat or excess energy of the first component to the second component. In such examples, any number of elements may be used to facilitate the transfer of heat from the first component to the second component, such as, a fluid (such as air), a heat absorbing material, a heat transporting conduit, etc.

In examples, moveable member 120 may be a component to couple to computing device 10. In examples, moveable member 120 may be a component that may be moved from a closed state to an open state. As used herein, a “closed state” refers to a state in which a component is disposed substantially within chassis 100. For examples, in a closed state, a first surface of a component may be a part of an outer surface of computing device 10. In contrast, an “open state” refers to a state in which a component is disposed substantially outside chassis 100. In other words, in an open state, the component may extend beyond an outer surface of chassis 100 as defined in the closed state. In examples, moveable member 120 may be disposed substantially within chassis 100 in a closed state and may substantially protrude from chassis 100 in an open state. In some examples, in the open state, moveable member 120 may be disposed to allow for air flow into an internal environment of chassis 100.

In the example of FIG. 1, moveable member 120 may transition from a closed state to an open state by moving along a directional arrow 122. In some examples, moveable member 120 may be coupled to computing device 10 to slide from chassis 100 along directional arrow 122. In other examples, moveable member 120 may be coupled to computing device 10 to rotate from a surface of chassis 100 to be disposed in a location along directional arrow 122. In some such examples, moveable member 120 may be coupled to device 10 to rotate about an axis formed in chassis 100. In an example, the axis formed in chassis 100 may be formed by a hinge. In other examples, moveable member 120 may slide and rotate along directional arrow 122.

In examples, moveable member 120 may include a frame to couple to computing device 10. In some such examples, a frame of moveable member 120 may be composed of a thermally insulating material to insulate moveable member 120 from heat dissipated by heat dissipating element 140. In such an example, the frame of moveable member 120 may extend around a portion of heat dissipating element 140 to protect a user from harm by touching a hot portion of heat dissipating element 140. In some examples, the insulating material may be at least one of fiberglass; mineral wool, mineral fiber, mineral cotton, mineral fibre, man-made mineral fibre (MMMF), man-made vitreous fiber (MMVF), glass wool, ceramic fibers, cellulose, calcium silicate, cellular glass, elastomeric foam, phenolic foam, vermiculite, polyurethane foam, polystyrene foam in polymeric resins (thermoplastic or thermoset resins), etc.

In examples, heat dissipating element 140 may be any element to dissipate heat. In examples, heat dissipating element 140 may be coupled to moveable member 120 to be exposed to an environment external to chassis 100 in the open state. In some examples, heat dissipating element 140 may be a heat sink. A “heat sink” refers to an element to absorb and dissipate heat. In examples, a heat sink may be used to absorb and dissipate heat generated in an electrical or mechanical device. Some heat sinks operate by absorbing heat from heat generating devices or components and providing a surface area from which the heat may be dissipated to a surrounding environment. In some heat sinks, a single or series of protrusions or fins may be used to increase the surface area from which heat may be dissipated to the surrounding environment. In some examples, fins may be integrated into heat dissipating element 140. In other examples, fins may be coupled to heat dissipating element 140 via any thermally conductive coupling. In examples, an insulating layer may be formed or disposed on heat dissipating element 140 to insulate a portion thereof. In such examples, the insulated portion of a heat dissipating element may remain within a temperature range safe for human usage.

As the environment or area surrounding a heat dissipating element absorbs dissipated heat, the temperature of that environment may increase. In examples, heat dissipating elements may be disposed in a device in a manner to dissipate heat to an area within the device or surrounding the device which may not be damaged or as readily damaged by the dissipated heat or may not cause injury to an operator. However, as discussed above, as computing devices become smaller, there are fewer areas of the device or surrounding the device which may not be damaged by dissipated heat or cause injury to an operator. In the example of FIG. 1, heat dissipating element 140 may be coupled to moveable member 120. In such an example, moveable member 120 may move, transition, or eject heat dissipating element 140 to a location outside chassis 100 of computing device 10 which may safely absorb dissipated heat therefrom. In other words, the location of moveable member 120 in the open state may be selected to reduce reintroduction of heat into chassis 100 to maintain or decrease an internal temperature of chassis 100 when moveable member 120 is in the open state.

In an example, heat dissipating element 140 may be thermally coupled to heat generating element 110 to absorb and dissipate heat therefrom. In some examples, heat dissipating element 140 may be thermally coupled to heat generating element 110 in a closed state of moveable member 120. In such examples, heat dissipating element 140 may be thermally isolated from heat generating element 110 when in the open state. In such an example, in operation, transitioning heat dissipating element 140 from a closed state to an open state may allow heat dissipating element 140 to cool down by dissipating heat to an environment surrounding chassis 100, In some examples, heat dissipating element 140, once cooled, may be transitioned to a closed state to thermally couple with heat generating element 110 to absorb and dissipate heat therefrom. In other examples, heat dissipating element 140 may be thermally coupled to heat generating element 110 in an open state of moveable member 120. In such an example, in operation, transitioning heat dissipating element 140 from a closed state to an open state may allow heat dissipating element 140 to dissipate heat received from heat generating element 110 while in the open state.

In examples, motor 170 may be any type of motor to be housed in chassis 100 of computing device 10. As used herein, a “motor” may be any mechanical or electrical component to provide mechanical energy to another component. In examples, motor 170 may be coupled to moveable member 120 to provide mechanical energy to move moveable member 120 from the closed state to the open state. In examples, motor 170 may move, transition, or eject moveable member 120 from the closed state to the open state in response to a temperature within chassis 100 exceeding a threshold. In examples, computing device 10 may include a temperature sensor to determine a temperature within chassis 100. In some examples, a temperature within chassis 100 may be a temperature at any location within chassis 100. In other examples, a temperature within chassis 100 may be a temperature at a specific location within chassis 100. In examples, in operation, when moveable member 120 is moved to the open state by motor 170, heat dissipating element 140 is moved outside of chassis 100 and exposed to an external environment. In such an example, heat dissipating element 140 may dissipate any heat therefrom to the external environment around computing device 10 rather than to an environment internal to chassis 100. In examples, the threshold temperature may be determined according to the heat sensitivity of different components housed within chassis 100 of computing device 10. In some such examples, the heat sensitivity of different components housed within chassis 100 may vary according the usage of the components. In such an example, the threshold temperature may dynamically change according to usage conditions of computing device 10. In examples, computing device 10 may include a processing resource to determine a threshold temperature.

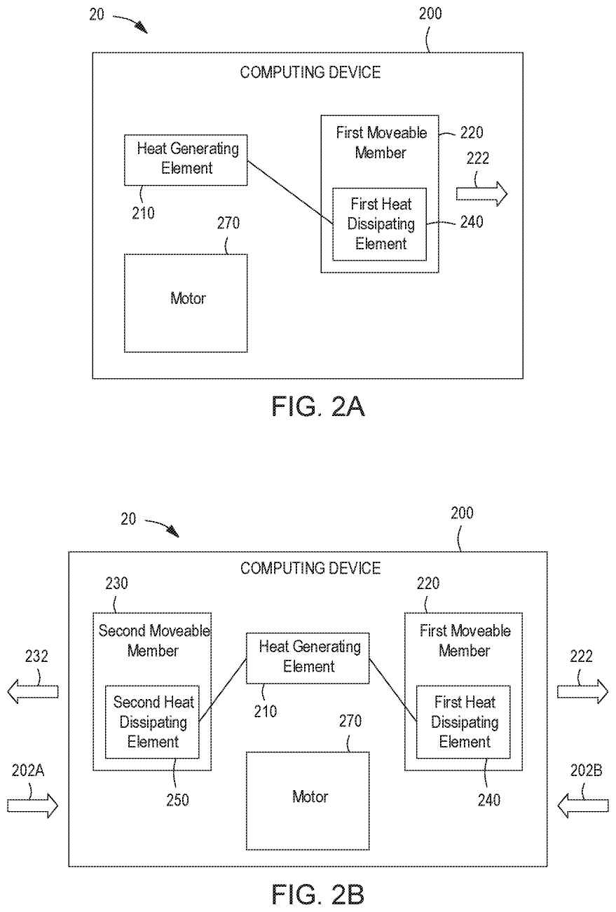

FIG. 2A is a block diagram of an example computing device 20. In examples, computing device 20 may include a chassis 200, a heat generating element 210, a first moveable member 220, a first heat dissipating element 240, and a motor 270.

In examples, chassis 200 may house a heat generating element 210 and a motor 270. In examples, first moveable member 220 may be coupled to first heat dissipating element 240. In examples, chassis 200 may house first moveable member 220 and first heat dissipating element 240 in a closed state. In contrast, in an open state, first moveable member 220 and first heat dissipating element 240 may be disposed outside chassis 200.

In examples, first heat generating element 210 may be any electrical or mechanical component which may generate heat in a computing device as described above with respect to FIG. 1, In examples, first heat generating element 210 may be disposed in any location within chassis 200 of computing device 20. In examples, first heat generating element 210 may be thermally coupled to heat first dissipating element 240.

In examples, first moveable member 220 may be a component to couple to computing device 20. In examples, first moveable member 220 may be a component that may be moved from a closed state to an open state. In examples, first moveable member 220 may be disposed substantially within chassis 200 in a closed state. In examples, first moveable member 220 may substantially protrude from chassis 200 in an open state. In some examples, in the open state, moveable member 220 may be disposed to allow for air flow into an internal environment of chassis 200.

In the example of FIG. 2A, first moveable member 220 may transition from a closed state to an open state by moving along a directional arrow 222, In some examples, first moveable member 220 may be coupled to computing device 20 to slide from chassis 200 along directional arrow 222. In other examples, first moveable member 220 may be coupled to computing device 20 to rotate from a surface of chassis 200 to be disposed in a location along directional arrow 222. In some such examples, first moveable member 220 may be coupled to computing device 20 to rotate about an axis formed in chassis 200. In an example, the axis formed in chassis 200 may be formed by a hinge. In other examples, first moveable member 220 may slide and rotate along directional arrow 222.

In examples, first moveable member 220 may include a frame to couple to computing device 20. In some such examples, a frame of first moveable member 220 may be composed of a thermally insulating material to insulate first moveable member 220 from heat dissipated by first heat dissipating element 240. In such an example, the frame of first moveable member 220 may extend around a portion of first heat dissipating element 240 to protect a user from harm by touching a hot portion of first heat dissipating element 240. In some examples, the insulating material may be any insulating material described above with reference to FIG. 1.

In examples, first heat dissipating element 240 may be any element to dissipate heat. In examples, first heat dissipating element 240 may be coupled to first moveable member 220 to be exposed to an environment external to chassis 200 in the open state. In some examples, first heat dissipating element 240 may be a heat sink. In some examples, fins may be integrated into first heat dissipating element 240. In other examples, fins may be coupled to first heat dissipating element 240 via any thermally conductive coupling. In examples, an insulating layer may be formed or disposed on first heat dissipating element 240 to insulate a portion thereof. In such examples, the insulated portion of a heat dissipating element may remain within a temperature range safe for human usage.

In the example of FIG. 2A, first heat dissipating element 240 may be coupled to first moveable member 220. In such an example, first moveable member 220 may move, transition, or eject first heat dissipating element 240 to a location outside chassis 200 of computing device 20 which may safely absorb dissipated heat therefrom. In other words, the location of first moveable member 220 in the open state may be selected to reduce reintroduction of heat into chassis 200 to maintain or decrease an internal temperature of chassis 200 when first moveable member 220 is in the open state.

In an example, first heat dissipating element 240 may be thermally coupled to heat generating element 210 to absorb and dissipate heat therefrom. In some examples, first heat dissipating element 240 may be thermally coupled to heat generating element 210 in a closed state of first moveable member 220. In such examples, first heat dissipating element 240 may be thermally isolated from heat generating element 210 when in the open state. In such an example, in operation, transitioning first heat dissipating element 240 from a closed state to an open state may allow first heat dissipating element 240 to cool down by dissipating heat to an environment surrounding chassis 200. In some examples, first heat dissipating element 240, once cooled, may be transitioned to a closed state to thermally couple with heat generating element 210 to absorb and dissipate heat therefrom. In other examples, first heat dissipating element 240 may be thermally coupled to first heat generating element 210 in an open state of first moveable member 220. In such an example, in operation, transitioning first heat dissipating element 240 from a closed state to an open state may allow first heat dissipating element 240 to dissipate heat received from heat generating element 210 while in the open state.

In examples, motor 270 may be any type of motor to be housed in chassis 200 of computing device 20. In examples, motor 270 may be coupled to first moveable member 220 to provide mechanical energy to move first moveable member 220 from the closed state to the open state. In examples, motor 270 may move, transition, or eject first moveable member 220 from the closed state to the open state in response to a temperature within chassis 200 exceeding a threshold. In examples, computing device 20 may include a temperature sensor to determine a temperature within chassis 200. In some examples, a temperature within chassis 200 may be a temperature at any location within chassis 200. In other examples, a temperature within chassis 200 may be a temperature at a specific location within chassis 200. In examples, in operation, when first moveable member 220 is moved to the open state by motor 270, first heat dissipating element 240 is moved outside of chassis 200 and exposed to an external environment. In such an example, first heat dissipating element 240 may dissipate any heat therefrom to the external environment around computing device 20 rather than to an environment internal to chassis 200. In examples, the threshold temperature may be determined according to the heat sensitivity of different components housed within chassis 200 of computing device 20. In some such examples, the heat sensitivity of different components housed within chassis 200 may vary according the usage of the components. In such an example, the threshold temperature may dynamically change according to usage conditions of computing device 20. In examples, computing device 20 may include a processing resource to determine a threshold temperature.

FIG. 2B is a block diagram of an example computing device including possible additional example components of computing device 20 of FIG. 2. Additional components may include second moveable member 230 and second heat dissipating element 250.

A second moveable member 230 may be a component to couple to computing device 20. In examples, second moveable member 230 may be a component that may be moved from a closed state to an open state. In examples, second moveable member 230 may be disposed substantially within chassis 200 in a closed state. In examples, second moveable member 230 may substantially protrude from chassis 200 in an open state. In some examples, in an open state, second moveable member 230 may disposed to allow for air flow into an internal environment of chassis 200. In the example of FIG. 2B, second moveable member 230 may be transitioned from a closed state to an open state by moving along a directional arrow 232. In some examples, second moveable member 230 may be coupled to computing device 20 to slide from chassis 200 along directional arrow 232. In other examples, second moveable member 230 may be coupled to computing device 20 to rotate from chassis 200 along directional arrow 232. In some such examples, second moveable member 230 may be coupled to device 20 to rotate about an axis formed in chassis 200, such as, an axis formed by a hinge. In other examples, second moveable member 230 may slide and rotate along directional arrow 232.

In examples, second heat dissipating element 250 may be any element to dissipate heat. In some examples, second heat dissipating element 250 may be a heat sink. In the example of FIG. 2, second heat dissipating element 250 may be coupled to second moveable member 230. In examples, second heat dissipating element 230 may be thermally coupled to heat generating element 210 to absorb and dissipate heat therefrom. Although depicted as thermally coupled to heat generating element 210, the examples are not limited thereto, and second heat generating element 210 may be thermally coupled to a different heat generating element instead of or in conjunction with heat generating element 210 (not shown). In some examples, second heat dissipating element 250 may be thermally coupled to heat generating element 210 in a closed state of second moveable member 230. In some examples, second heat dissipating element 250 may be thermally coupled to heat generating element 210 in an open state of second moveable member 230.

In the example of FIG. 2B, motor 270 may be coupled to second moveable member 230 to provide mechanical energy to move, transition, or eject second moveable member 230 from the closed state to the open state. In other examples, a second motor (not shown) may be coupled to second moveable member 230 to provide mechanical energy to move, transition, or eject second moveable member 230 from the closed state to the open state. In examples, motor 270 may transition second moveable member 230 from the closed state to the open state in response to a temperature within chassis 200 exceeding a threshold. In some examples, the threshold temperature to transition second moveable member 230 to the open state may be the same as the threshold temperature to transition first moveable member 220 to the open state. In other examples, the threshold temperature to transition second moveable member 230 to the open state may be a second threshold temperature differing from the threshold temperature to transition first moveable member 220 to the open state.

In examples, second moveable member 230 may be disposed to extend from a surface of chassis 200 opposite to the surface of chassis 200 from which first moveable member 220 may extend. In such an example, an air flow path may be established through chassis 200 between second moveable member 230 and first moveable member 220 along a directional arrow 202A. In other such examples, an air flow path may be established through chassis 200 between second moveable member 230 and first moveable member 220 along a directional arrow 202B.

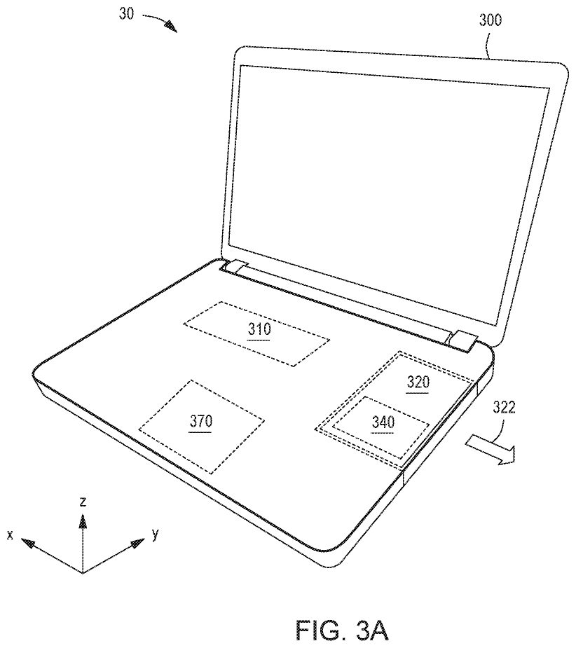

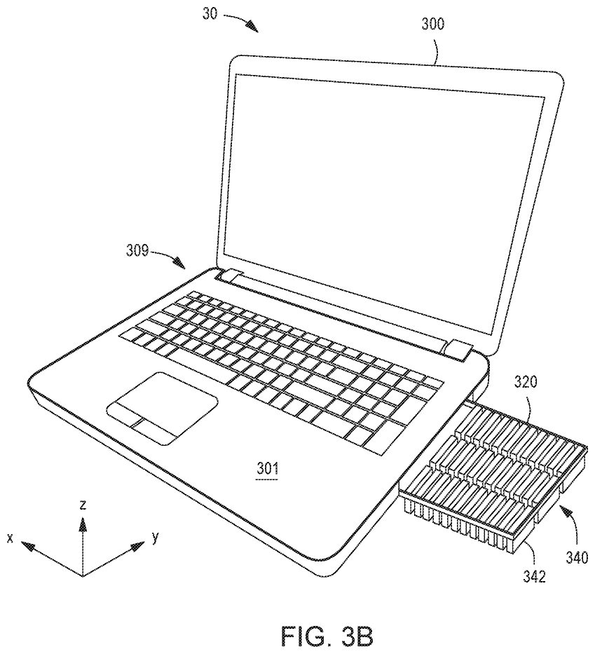

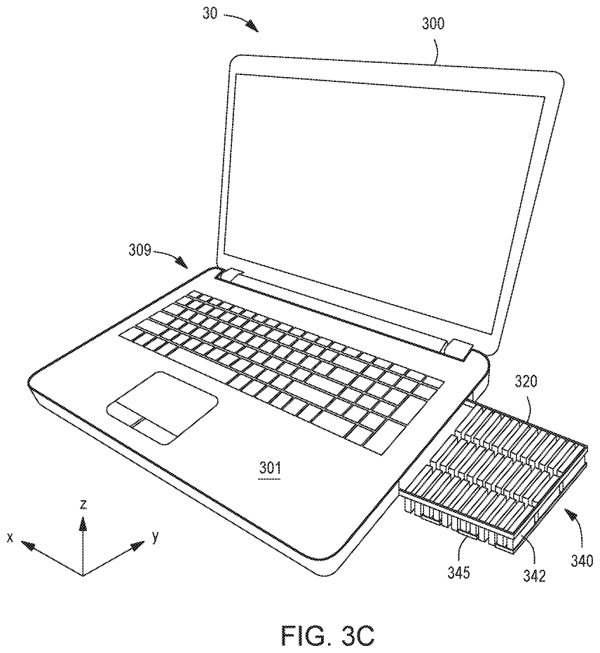

FIGS. 3A-3B are examples of a computing device 30 including a heat dissipating element 340. FIG. 3A includes a chassis 300 to house a heat generating component 310, a moveable member 320, a heat dissipating element 340, and a motor 370. FIG. 3B depicts an example of computing device 30 of FIG. 3A with heat dissipating element 340 and moveable member 320 disposed outside of chassis 300. In the example of FIG. 3B, an internal temperature of chassis 300 may have exceeded a threshold temperature and motor 370 (not shown in FIG. 3B) may have moved moveable member 320 to an open state to expose heat dissipating element 340 to an external environment of computing device 30. In examples, heat dissipating element 340 may include a fin 342 extending therefrom. In the example of FIG. 3B, a plurality of fins 342 may be coupled heat dissipating element 340 to extend downward therefrom along the negative z-axis. In such examples, fins 342 may provide a surface area of heat dissipating element 340 from which heat may be dissipated to the surrounding atmosphere. As will be appreciated, in other examples, fins 342 may be disposed to extend upward from heat dissipating element 340.

In the example of FIG. 3B, in operation, computing device 30 may monitor an internal temperature in chassis 300, for example, with a thermometer. When the internal temperature exceeds a threshold, motor 370 may eject, transition, or move moveable member 320 to an open state or outside of chassis 300. In such examples, when moveable member 320 is disposed in the open state or outside chassis 300 heat dissipated by heat dissipating element 340 is provided to the atmosphere outside chassis 300 rather than an internal volume of chassis 300. In examples, the transition or movement of moveable member 320 to the open state may result in an internal temperature of chassis 300 remaining stable as heat dissipating element 340 dissipates heat to the environment outside chassis 300. In such examples, the threshold temperature may be selected to ensure computing device 30 may operate at such threshold temperature.

In the example of FIG. 3B, a keyboard tray 309 may be integrated into a surface 301 of chassis 300. As used herein, a “keyboard tray” refers to opening(s) to receive key(s) or buttons for a keyboard. In examples, surface 301 of chassis 300 may be parallel to a surface of moveable member 320 disposed along a direction of ejection of moveable member 320 indicated by a directional arrow 322 (shown in FIG. 3A). As will be appreciated, in other examples, surface 301 may be angled with respect to a “top” surface of a moveable member 320 when ejected, transitioned, or moved into an open state.

In an example, the transition, ejection, or movement of moveable member 320 to the open state may result in an internal temperature of chassis 300 being reduced as heat dissipating element 340 dissipates heat to the environment outside chassis 300. For example, an internal temperature of chassis 300 may be reduced by cooler external air entering chassis 300 when moveable member 320 is in the open state. In some examples, motor 370 may eject, transition, or move moveable member 320 from an open state to a closed state when a temperature inside chassis 300 falls below the threshold temperature. In other examples, motor 370 may eject, transition, or move moveable member 320 from an open state to a closed state after a specific duration of time. For example, the duration of time may be a chosen to allow computing device 30 to reduce an internal temperature thereof by a specific amount.

FIG. 3C is an example of computing device including possible additional example components of computing device 30 of FIG. 3A. In the example of FIG. 3C, heat dissipating element 340 and moveable member 320 are disposed outside of chassis 300. Additional components may include a heat insulation layer 345. In examples, heat insulation layer 345 may be disposed on a distal end of at least a portion of fins 342 of heat dissipating element 340. As depicted, heat insulation layer 345 may be disposed to insulate a bottom surface of first heat dissipating element 340 along a positive z-direction. In some examples, heat insulation layer 345 may be any thermally insulating material to thermally insulate the distal end of fins 342. In some examples, heat insulation layer 345 may be any heat insulating material described above with respect to FIG. 1. In an example, heat insulation layer 345 may insulate the distal end of at least some of fins 342 from heat generated by heat generating component 310. In such an example, the amount of heat radiated by some of the distal ends of fins 342 may be reduced thereby reducing an ambient temperature surrounding the distal end of fins 342 compared to the example of FIGS. 3A-3B in which there is no heat insulation layer 345. In such an example, the temperature of some of the distal ends of the plurality of fins 342 may remain within a human safe range. In some examples, between approximately 0.1 mm and approximately 10 mm of heat insulation layer 345 may be disposed on the distal end of fins 342.

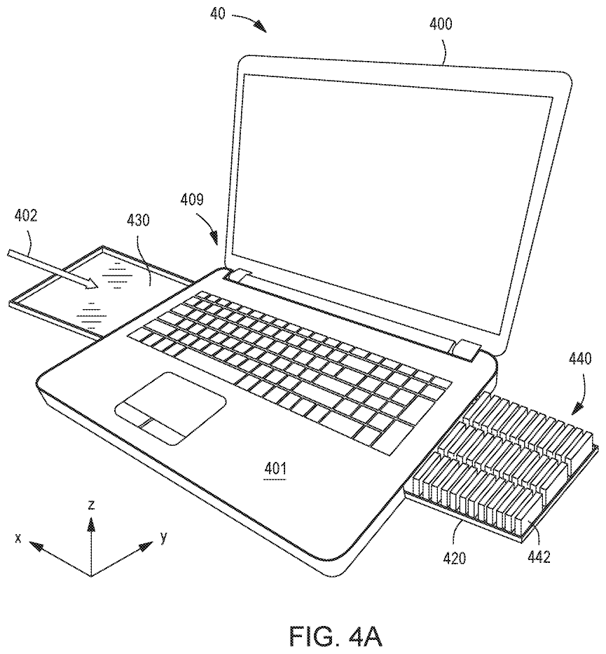

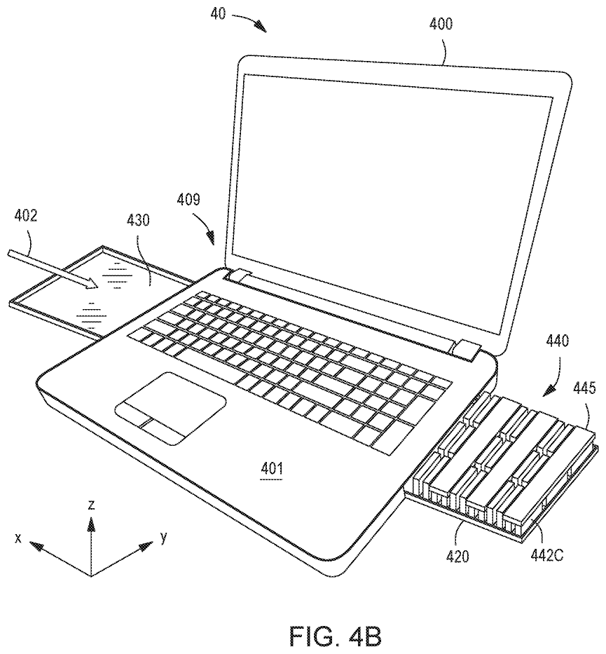

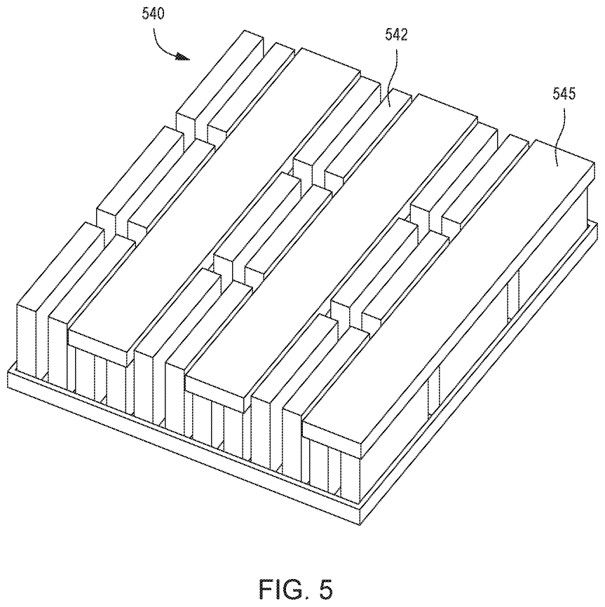

FIG. 4A is an example of a computing device 40 including a heat dissipating element 440. FIG. 4A includes a chassis 400 to house a heat generating component (not shown), a first moveable member 420, a second moveable member 430, a heat dissipating element 440, and a motor (not shown). In the example, heat dissipating element 440 may be coupled to first moveable member 420. In the example of FIG. 4A, first moveable member 420 and second moveable member 430 may be disposed outside of chassis 400. In such an example, an internal temperature of chassis 400 may have exceeded a threshold temperature and a motor may have moved first moveable member 420 and second moveable member 430 to an open state. In such examples, first moveable member 420 being outside chassis 400 may expose heat dissipating element 440 to an external environment surrounding computing device 40. In examples, heat dissipating element 440 may include a plurality of fins 442 extending therefrom. In the example of FIG. 4A, fins 442 may extend upwards from heat dissipating element 400 along a positive z-direction. In such an example, a distal end of fins 442 may be substantially parallel to a surface 401 of chassis 400 into which a keyboard tray 409 may be integrated. As will be appreciated, in other examples, fins 442 may be disposed to extend downward from heat dissipating element 440.

In an example, an air flow path may be established through chassis 400 along a directional arrow 402 to provide ambient air to internal compartment(s) of chassis 400. Although depicted as traveling from second moveable member 430 to first moveable member 420, it will be appreciated that an air flow path may be established in a reverse direction or any other direction according to the movement of air in an environment external to chassis 400. In the example of FIGS. 4A-4B, both first moveable member 420 and second moveable member 430 have been moved to an open state. In the examples, in operation, computing device 40 may monitor an internal temperature in chassis 400, for example, with a thermometer. When the temperature exceeds a threshold, a motor (not shown) may eject, transition, or move first moveable member 420 to an open state or outside of chassis 400. In such an example, the motor may eject, transition, or move second moveable member 430 to an open state or outside of chassis 400 when the threshold temperature is exceeded. In other such examples, the motor may eject, transition, or move second moveable member 430 to an open state or outside of chassis 400 when a different threshold temperature is exceeded. In examples, generated heat may be dissipated from computing device 40 by both an air flow path (i.e., along directional arrow 402) and heat generating element 440 to an environment external to chassis 400. In some examples, the motor may eject, transition, or move first moveable member 420 and second moveable member 430 from an open state to a closed state when a temperature inside chassis 400 falls below the threshold temperature. In other examples, the motor may eject, transition, or move first moveable member 420 and second moveable member 430 from an open state to a closed state after a specific duration of time. For example, the duration of time may be chosen to allow computing device 40 to reduce an internal temperature thereof by a specific amount.

FIG. 4B is an example of computing device including possible additional example components of computing device 40 of FIG. 4A. Additional components may include a heat insulation layer 445. In examples, heat insulation layer 445 may be disposed on a distal end of at least a portion of fins 442 of first heat dissipating element 440. As depicted, heat insulation layer 445 may be disposed to insulate a top surface of first heat dissipating element 440 along a positive z-direction. In some examples, heat insulation layer 445 may be any thermally insulating material to thermally insulate the distal end of fins 442. In some examples, heat insulation layer 445 may be comprised of any of the materials described with respect to FIG. 1. In an example, heat insulation layer 445 may insulate the distal end of at least some of fins 442 from heat generated by a heat generating component (not shown). In such an example, the amount of heat radiated by some of the distal ends of fins 442 may be reduced thereby reducing an ambient temperature surrounding the distal end of fins 442 compared to the example of FIG. 4A in which there is no heat insulation layer 445. In such an example, the temperature of some of the distal ends of the plurality of fins 442 may remain within a human safe range. In some examples, between approximately 0.1 mm and approximately 10 mm of heat insulation layer 445 may be disposed on the distal end of fins 442.

FIG. 5 is examples of a heat dissipating element 540. In the example of FIG. 5, heat dissipating element 540 may include a plurality of fins 542 and a heat insulation layer 545. In examples, heat insulation layer 545 may be disposed on less than an entire surface area of the distal end of fins 542. In such an example, the ambient temperature surrounding the distal end of some of the plurality of fins 542 may be reduced compared to an example in which there is no heat insulation layer 545 is disposed thereon. Although depicted as having a rectangular cross-section in the example of FIG. 5, heat insulation layer 545 may be of any cross-sectional shape to cover a portion of the distal end of fins 542. Furthermore, although FIG. 5 depicts a plurality of fins 542 with the same shaped deposition of heat insulation layer 545, the examples are not limited thereto and the shape of some or all of the depositions of heat insulation layer 545 on the plurality of fins 542 in FIG. 5 may be different from each other. As will be appreciated, the use of a heat insulation layer 542 that partially covers the distal end of fins 542 may protect a user from encountering a hot surface of the fins while allowing heat to dissipate from the surfaces of fins without an insulation layer disposed thereon. In some examples, some of the plurality of fins 542 may have a deposition of heat insulation layer 545 that completely covers the distal ends of the plurality of fins 542. In the example of FIG. 5, heat insulation layer 545 is depicted as disposed to form a top surface of heat dissipating element 540. As will be appreciated, heat insulation layer 545 may disposed in a computing device in any orientation such that a heat insulation layer may form a top surface, a bottom surface, a right-side surface, or a left-side surface of heat dissipating element.

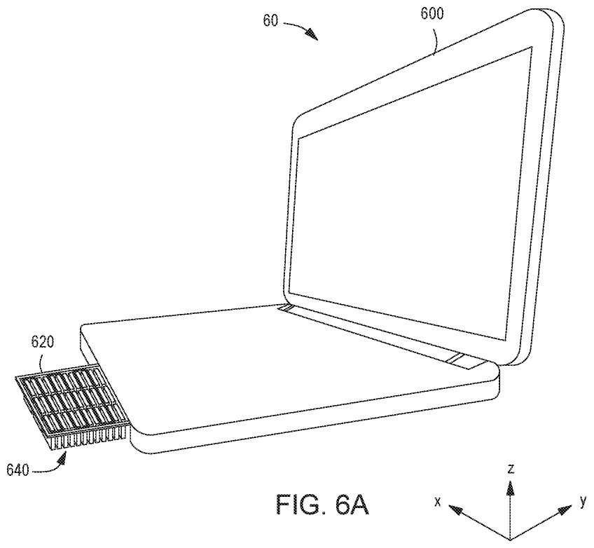

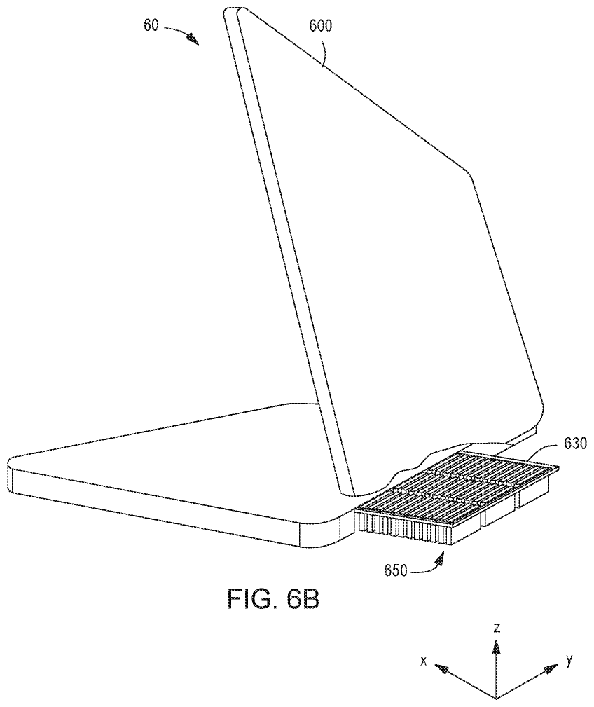

FIGS. 6A-6B are examples of a computing device 60 including heat dissipating elements. In the example of FIG. 6A, a first moveable member 620 is shown in an open state. In the example of FIG. 6B, a second moveable member 630 is shown in an open state. In examples, first moveable member 620 and second moveable member 630 are coupled to computing device 60 to protrude from opposing surface thereof. In the example of FIG. 6A, a first heat dissipating element 640 is coupled to first moveable member 620 such that a plurality of fins of first heat dissipating element 640 extend downward therefrom. Similarly, as shown in FIG. 6B, a second heat dissipating element 650 is coupled to second moveable member 630 such that a plurality of fins of second heat dissipating element 650 extend downward therefrom. In examples, first moveable member 620 and second moveable member 630 may be substantially similar to moveable members described with respect to FIGS. 1-4B and additional descriptions thereof will be omitted. Similarly, first heat dissipating element 640 and second heat dissipating element 650 may be substantially similar to heat dissipating elements described with respect to FIGS. 1-5 and additional descriptions thereof will be omitted.

In the example of FIGS. 6A-6B, first moveable member 620 and second moveable member 630 may be moved to the open state when a threshold temperature is exceeded. In some examples, the threshold temperature to eject, transition, or move first moveable member 620 to the open state may be different from the threshold temperature to eject, transition, or move second moveable member 630. FIG. 6A depicts a state in which the threshold temperature to eject, transition, or move first moveable member 620 to the open state has been exceeded. FIG. 6B depicts a state in which the threshold temperature to eject, transition, or move second moveable member 630 to the open state has been exceeded. As described with respect to FIG. 3A-30, when first heat dissipating element 640 or second moveable member 630 is disposed outside chassis 600 of device 60, heat dissipated thereby may be conveyed outside chassis 600 to either reduce or stabilize a temperature inside chassis 600. As will be appreciated, when both first moveable member 620 and second moveable member 630 are disposed outside chassis 600, an air flow path (not shown) may be established through chassis 600 therebetween.

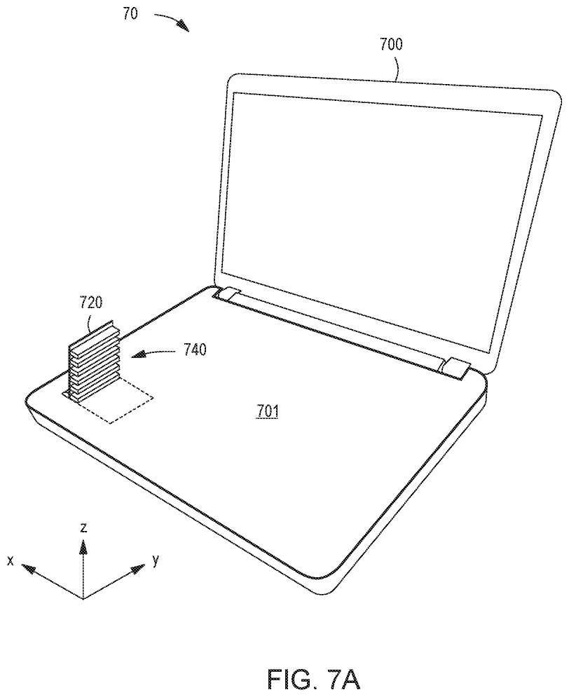

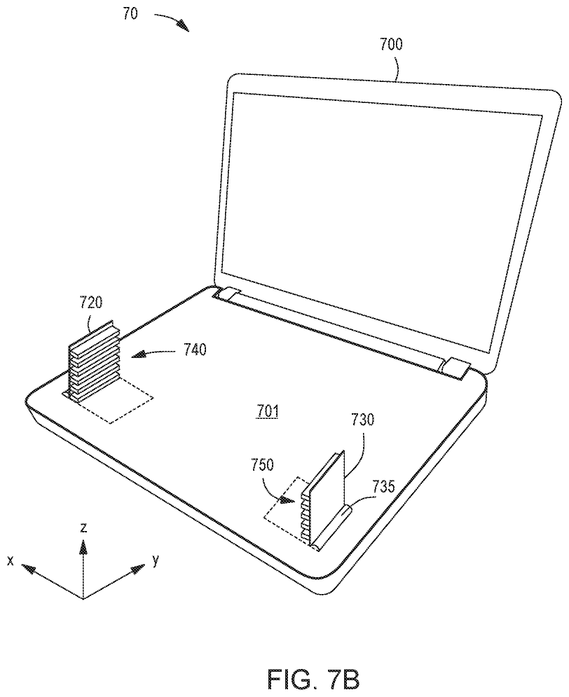

FIGS. 7A-7B are examples of a computing device 70 including heat dissipating elements. In the examples, computing device 70 may include a chassis 700, a first moveable member 720, a second moveable member 730, a first heat dissipating element 740, and a second heat dissipating element 750. In examples, first moveable member 720 and second moveable member 730 are coupled to chassis 700 to eject, transition, or move rotationally about respective axes to enter the open state. In the example of FIG. 7A, a first moveable member 720 is shown in an open state and second moveable member 730 is not visible. In the example of FIG. 7A, first moveable member 720 is coupled to chassis 700 to eject, transition, or move rotationally about an axis (not visible in FIG. 7A) to enter the open state. In the example of FIG. 7B, first moveable member 720 and second moveable member 730 are shown in an open state. In the example of FIG. 7B, second moveable member 730 rotates about axis 735 integrated into a surface 701 of computing device 70. In examples, first moveable member 720 and second moveable member 730 may be substantially similar to moveable members described with respect to FIGS. 1-6B and additional descriptions thereof will be omitted. Similarly, first heat dissipating element 740 and second heat dissipating element 750 may be substantially similar to heat dissipating elements described with respect to FIGS. 1-6B and additional descriptions thereof will be omitted. As will be appreciated, an air flow path may be established to provide external air to an internal volume of chassis 700 in both FIGS. 7A and 7B,

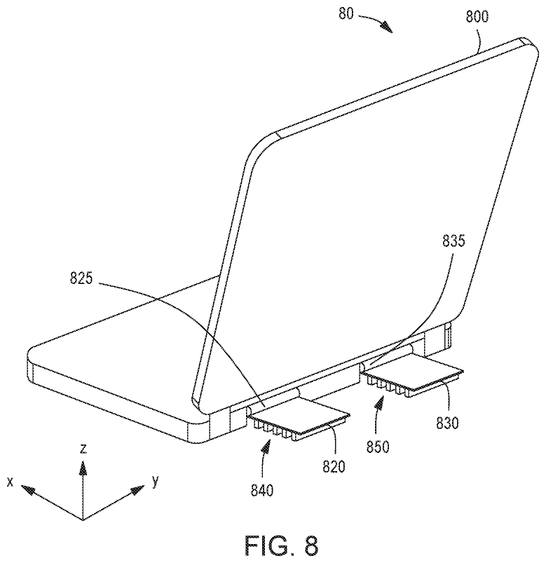

FIG. 8 is an example of a computing device 80 including heat dissipating elements. In the examples, computing device 80 may include a chassis 800, a first moveable member 820, a second moveable member 830, a first heat dissipating element 840, and a second heat dissipating element 850. In examples, first moveable member 820 and second moveable member 830 may be substantially similar to moveable members described with respect to FIGS. 1-7B and additional descriptions thereof will be omitted. Similarly, first heat dissipating element 840 and second heat dissipating element 850 may be substantially similar to heat dissipating elements described with respect to FIGS. 1-7B and additional descriptions thereof will be omitted.

In examples, first moveable member 820 and second moveable member 830 are coupled to chassis 800 to eject, transition, or move rotationally about respective axes to enter the open state. In the example of FIG. 8, a first moveable member 820 and a second moveable member 830 are shown in an open state. In the example of FIG. 8, first moveable member 820 and a second moveable member 830 are disposed to rotate from a back surface of chassis 800 into the open state. In examples, first moveable member 820 may rotate about first axis 825 and second moveable member 830 may rotate about second axis 835. Although depicted as substantially parallel first axis 825 and second axis 835 may be disposed in any arrangement to allow first moveable member 820 and a second moveable member 830 to rotate to an open state outside chassis 800. As will be appreciated, an air flow path may be established to provide external air to an internal volume of chassis 800 in FIG. 8.

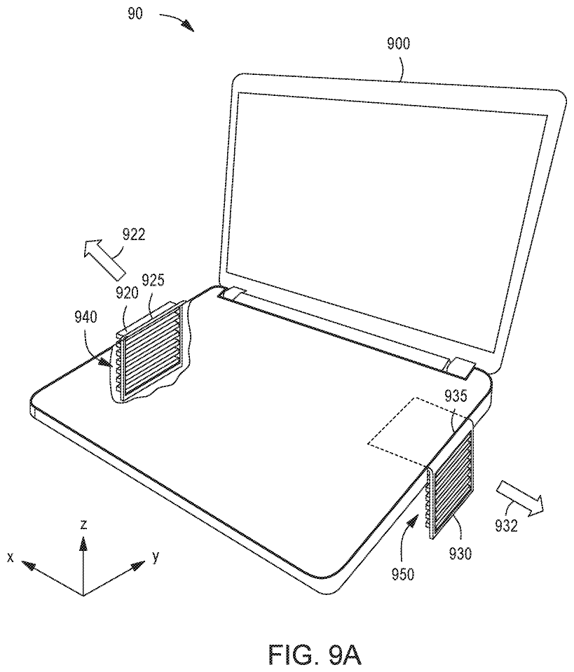

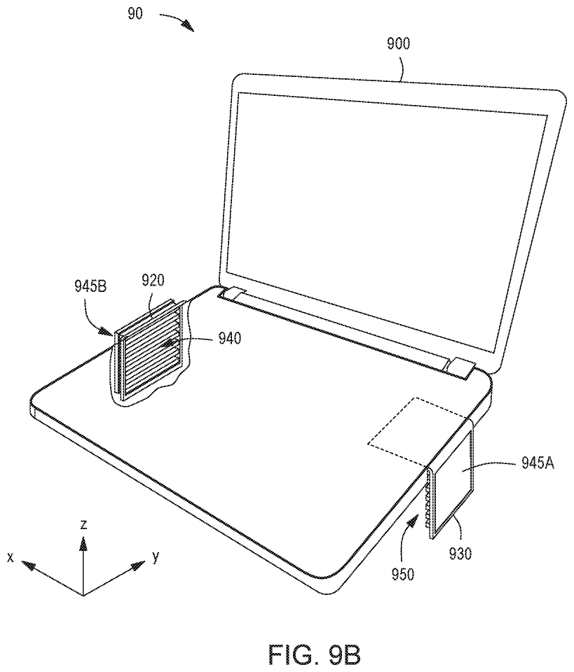

FIG. 9A is an example of a computing device 90 including heat dissipating elements. In the examples, computing device 90 may include a chassis 900, a first moveable member 920, a second moveable member 930, a first heat dissipating element 940, and a second heat dissipating element 950. In examples, first moveable member 920 is coupled to chassis 900 to eject, transition, or move rotationally about a first axis 925 to enter the open state. In the example of FIG. 9A, first moveable member 920 may move along directional arrows 922 and then rotate about axis 925 to be disposed as shown. In such an example, first heat dissipating element 940 is coupled to first moveable member 920 such that a plurality of fins extend outward therefrom along a positive x-direction. Similarly, in examples, second moveable member 930 is coupled to chassis 900 to eject, transition, or move rotationally about a second axis 935 to enter the open state. In the example of FIG. 9A, second moveable member 930 may move along directional arrows 932 and then rotate about second axis 935 to be disposed as shown. In such an example, second heat dissipating element 950 is coupled to second moveable member 930 such that a plurality of fins extend outward therefrom along a negative x-direction. In examples, first moveable member 920 and second moveable member 930 may be substantially similar to moveable members described with respect to FIGS. 1-8 and additional descriptions thereof will be omitted. Similarly, first heat dissipating element 940 and second heat dissipating element 950 may be substantially similar to heat dissipating elements described with respect to FIGS. 1-8 and additional descriptions thereof will be omitted.

FIG. 9B is an example of computing device including possible additional example components of computing device 90 of FIG. 9A. Additional components may include a first heat insulation layer 945A and second heat insulation layer 945B. In the examples, first heat insulation layer 945A is disposed on a distal end of the plurality of fins of first heat dissipating element 940 and second heat insulation layer 945B is disposed on a distal end of the plurality of fins of second heat dissipating element 950. In the example of FIG. 9B, first heat insulation layer 945A may form an entire surface of first heat dissipating element 940. Similarly, second heat insulation layer 945B may form an entire surface of second heat dissipating element 950. In such an example, the amount of heat radiated by first heat dissipating element 940 and second heat dissipating element 950 may be reduced thereby reducing an ambient temperature surrounding first heat dissipating element 940 and second heat dissipating element 950 compared to the example of FIG. 9A in which there is no first heat insulation layer 945A and second heat insulation layer 945B. In such an example, the temperature of a distal surface of first heat dissipating element 940 and a distal surface of second heat dissipating element 950 may remain within a human safe range. In some examples, first heat insulation layer 945A and second heat insulation layer 945B may be any thermally insulating material to thermally insulate the distal end of fins. In some examples, a first heat insulation layer 945A and second heat insulation layer 945B may be any heat insulating material described above with respect to FIG. 1. In some examples, between approximately 0.1 mm and approximately 10 mm of heat insulation layer may be disposed on first heat dissipating element 940 and second heat dissipating element 950. As will be appreciated, an air flow path may be established to provide external air to an internal volume of chassis 900 in both FIGS. 9A and 9B.

In the examples described herein, a computing device may include a heat dissipating element to thermally couple to a heat generating element. In examples, when a threshold temperature inside a chassis of the computing device is exceed, the heat dissipating element is moved to outside the chassis to dissipate heat to an external environment and may introduce external air to an internal volume of the chassis. As will be appreciated, in the examples described herein, heat may be dissipated from computing devices under the principles of heat radiation, heat convection, and thermal conduction. In such examples, the movement of the heat dissipating element to outside the chassis may protect the computing device from damage due to overheating while allowing a smaller form factor to be used for the chassis, for example, by eliminating other heat dissipating elements, such as a fan. Although depicted with a notebook or clam shell style computing device, the examples are not limited thereto, and the heat dissipating elements may be disposed in any type of computing device.

All of the features disclosed in this specification (including any accompanying claims, abstract and drawings), may be combined in any combination, except combinations where at least some of such features are mutually exclusive.

What is claimed is:

1. A computing device, comprising:
a chassis to house a heat generating element;
a moveable member within the chassis in a closed state, wherein the moveable member is to transition from the closed state to an open state;
a heat dissipating element coupled to the moveable member to be exposed to an external environment in the open state, the heat dissipating element to be thermally coupled to the heat generating element in the closed state of the moveable member; and
a motor to move the moveable member from the closed state to the open state in response to a temperature within the chassis exceeding a threshold.

2. The computing device of claim 1, wherein the heat dissipating element includes a heat insulation layer to insulate a portion of the heat dissipating element.

3. The computing device of claim 2, wherein the heat insulation layer is to insulate a top surface of the heat dissipating element.

4. The computing device of claim 2, wherein the heat insulation layer is to insulate a bottom surface of the heat dissipating element.

5. The computing device of claim 1, wherein the heat dissipating element, in the open state, is thermally coupled to the heat generating element.

6. The computing device of claim 1, further comprising a keyboard tray integrated into a surface of the chassis, the surface parallel to the moveable member along a direction of ejection of the moveable member.

7. A computing device, comprising:
a chassis to house a heat generating element;
a first moveable member within the chassis in a closed state, wherein the first moveable member is to eject from a first surface of the chassis to transition from the closed state to an open state, the chassis to be open to an external environment in the open state of the first moveable member;
a first heat dissipating element coupled to the first moveable member to be exposed to the external environment in the open state of the first moveable member, the first heat dissipating element to be thermally coupled to the heat generating element in a closed state of the first moveable member;
a second moveable member within the chassis in a closed state of the second moveable member, wherein the second moveable member is to eject from a second surface of the chassis in an open state of the second moveable member, the first surface disposed opposite the second surface, the chassis to be open to the external environment in the open state of the second moveable member; and
a motor to eject the first moveable member from the chassis in response to a temperature within the chassis exceeding a first threshold.

8. The computing device of claim 7, wherein the motor is to move the second moveable member into the open state of the second moveable member in response to a temperature within the chassis exceeding a second threshold.

9. The computing device of claim 7, wherein the first heat dissipating element includes a plurality of fins extending upwards from the first moveable member.

10. The computing device of claim 7, wherein the first heat dissipating element includes a plurality of fins extending downwards from the first moveable member.

11. The computing device of claim 7, wherein the first heat dissipating element includes a heat insulation layer to insulate a portion of the first heat dissipating element.

12. A computing device, comprising:
a chassis to house a heat generating element;
a first moveable member within the chassis in a closed state, wherein the first moveable member is to eject from the chassis to transition from the closed state to an open state, the chassis to be open to an external environment in the open state of the first moveable member;
a first heat dissipating element coupled to the first moveable member to be exposed to the external environment in the open state of the first moveable member, the first heat dissipating element to be thermally coupled to the heat generating element;
a second moveable member within the chassis in a closed state of the second moveable member, wherein the second moveable member is to eject from the chassis to transition from the closed state of the second moveable member to an open state of the second moveable member, the chassis to be open to the external environment in the open state of the second moveable member;
a second heat dissipating element coupled to the second moveable member to be exposed to the external environment in the open state of the second moveable member, the second heat dissipating element to be thermally coupled to the heat generating element; and
a motor to eject the first moveable member and the second moveable member from the chassis in response to a temperature within the chassis exceeding a first threshold temperature.

13. The computing device of claim 12, wherein the first heat dissipating element and the second heat dissipating element include a plurality of fins and a heat insulation layer.

14. The computing device of claim 12, wherein the motor is to eject the second moveable member into the open states of the second moveable member in response to a temperature within the chassis exceeding a second threshold temperature, wherein the second threshold temperature differs from the first threshold temperature.

15. The computing device of claim 12, wherein the first heat dissipating element and the second heat dissipating element are to be thermally isolated from the heat generating component in the open state.
